(19) United States
(12) Patent Application Publication
(10) Pub. No.: US 2014/0199842 A1
(43) Pub. Date: Jul. 17, 2014

(54) CHEMICAL MECHANICAL POLISHING PROCESS AND SLURRY CONTAINING SILICON NANOPARTICLES

(71) Applicant: Applied Materials, Inc., Santa Clara, CA (US)

(72) Inventors: Vishwas V. Hardikar, Campbell, CA (US); Zhihong Wang, Sunnyvale, CA (US); David Maxwell Gage, San Jose, CA (US); Thomas E. Gartner, III, San Francisco, CA (US)

(21) Appl. No.: 14/143,262

(22) Filed: Dec. 30, 2013

Related U.S. Application Data
(60) Provisional application No. 61/751,543, filed on Jan. 11, 2013.

(51) Int. Cl. H01L 21/306; H01L 21/67; C09G 1/02

(52) U.S. Cl. CPC H01L 21/30625; C09G 1/02; H01L 21/67092
USPC 438/693; 252/79.1; 156/345.12

(57) ABSTRACT

In one aspect, a substrate chemical mechanical polishing (CMP) method for substrates is disclosed. The CMP method includes providing a substrate having a surface of silicon and copper such as through silicon via regions containing copper, and polishing the surface with a slurry containing very small silicon nanoparticles (e.g., having an average diameter less than 8 nanometers). CMP systems and slurries for CMP are provided, as are numerous other aspects.

### RELATED APPLICATIONS

The present application claims priority to U.S. Provisional Application 61/751,543 filed Jan. 11, 2013, and entitled “CHEMICAL MECHANICAL POLISHING PROCESS AND SLURRY CONTAINING SILICON NANOPARTICLES” which is hereby incorporated herein for all purposes.

### FIELD

The present invention relates generally to semiconductor device manufacturing, and more particularly to chemical mechanical polishing using abrasive slurries.

### BACKGROUND

Within semiconductor substrate manufacturing, a planarization process may be used to remove various layers or films, such as silicon dioxide, silicon nitride, copper, or the like from a substrate (e.g., a patterned wafer). Planarization may be accomplished using a chemical mechanical polishing (CMP) process by instituting an abrasive slurry between a polishing pad and the substrate surface to be polished (e.g., planarized). The substrate is received in a holder that applies pressure against a side (e.g., front side or backside) of the substrate to force the substrate against the polishing pad. Both the holder and the polishing pad may be rotated to facilitate the material removal. Further, the holder may oscillate the substrate back and forth across the surface of the polishing pad.

During certain planarization processes, although adequate material removal may be accomplished with existing processes and slurries, other problems may be encountered. Accordingly, improved polishing methods and slurries are sought.

### SUMMARY

In a first aspect, a chemical mechanical polishing method of processing a substrate is provided. The chemical mechanical polishing method of processing a substrate includes providing a substrate having a surface containing silicon and copper, and polishing the surface with a slurry containing silicon nanoparticles.

In a first aspect, a chemical mechanical polishing method of processing a substrate is provided. The chemical mechanical polishing method includes providing a substrate having a backside surface of silicon and through silicon via regions containing copper, and polishing the backside surface with a slurry containing silicon nanoparticles.

In another aspect, a chemical mechanical polishing system is provided. The chemical mechanical polishing system includes a substrate held in a substrate holder, the substrate having a surface of silicon and copper; a polishing pad; a slurry containing silicon nanoparticles inserted between the substrate and the polishing pad.

In another aspect, a chemical mechanical polishing system is provided. The chemical mechanical polishing system includes a substrate held in a substrate holder, the substrate having a backside surface of silicon and through silicon via regions of copper, a polishing pad, and a slurry containing silicon nanoparticles inserted between the substrate and the polishing pad.

In another aspect, a slurry composition adapted to chemical mechanical polishing of a wafer is provided. The improved slurry composition includes a liquid carrier, and silicon nanoparticles having an average particle size of less than about 8 nanometers, and in an amount between about 0.01 weight % and about 0.1 weight % wherein the pH of the composition is between about 9 and about 12.

Other features and aspects of the present invention will become more fully apparent from the following detailed description of example embodiments, the appended claims, and the accompanying drawings.

### BRIEF DESCRIPTION OF THE DRAWINGS

FIG. 1 illustrates a partial side plan of a chemical mechanical polishing system according to embodiments.

FIG. 2 illustrates a cross-sectioned partial side view of a backside of a substrate (including through silicon via regions) being polished by a slurry comprising nanoparticles according to embodiments.

FIG. 3 illustrates a micrograph view of a portion of a backside surface of a substrate after a first expose polishing step wherein the through silicon via is exposed illustrating deposited copper/copper oxide particles according to embodiments.

FIG. 4 illustrates a micrograph view of a backside surface of a substrate after a second polishing step wherein some or all of any deposited copper/copper oxide around the through silica via is removed according to embodiments.

FIG. 5 illustrates a flowchart of a chemical mechanical polishing method of processing a substrate according to embodiments.

### DETAILED DESCRIPTION

Embodiments described herein relate to systems, slurries, and methods adapted to polish a surface of a substrate. In particular, chemical mechanical polishing methods and slurries adapted to provide through silicon via processing to expose backside via are provided. In particular, the method and slurries are used to prevent poisoning the silicon backside surfaces with copper.

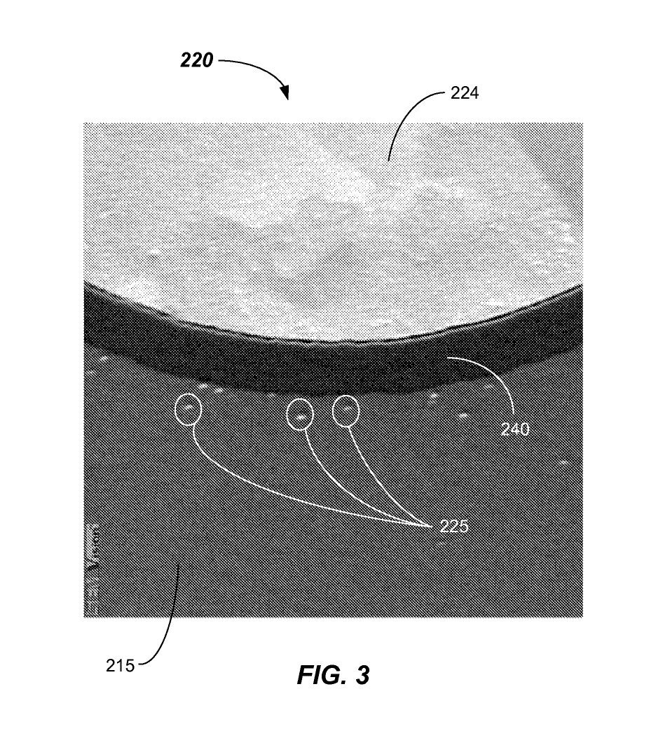

In particular, when a polishing step using abrasives is carried out to expose the through silicon via, copper and/or copper oxide particles are deposited on the silicon surfaces around the peripheries of the through silicon via (See FIG. 3). This poisons the transistors. To avoid this poisoning of the silicon backside, prior methods have used a multistep process of stopping short of breaking through to the copper vias on the backside, and then performing further deposition and zoned etching to expose the regions of copper through silicon vias. Thus, although prior systems have avoided copper contamination, simpler methods are desired.

In one or more embodiments, a chemical mechanical polishing method of processing a substrate is provided. The method includes providing a substrate having a backside surface of silicon and exposed through silicon via regions of copper thereon. The backside surface is then polished with a slurry containing silicon nanoparticles. The silicon nanoparticles are extremely small so that they possess large surface area which can effectively bind to free copper removed by the small particles. Also, a chemical mechanical polishing system is provided having a substrate holder, the substrate having a backside surface of silicon and through silicon via regions of copper, a polishing pad, and a slurry containing silicon nanoparticles inserted between the substrate and the polishing pad. CMP slurries including the silicon nanoparticles are provided, as are other aspects.

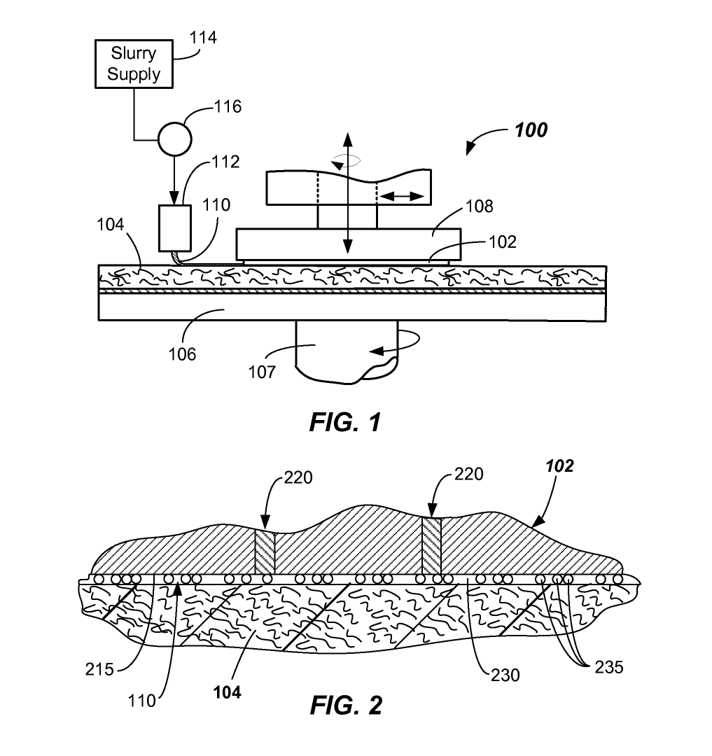

These and other aspects of embodiments of the invention are described below with reference to FIGS. 1-5 herein.

FIG. 1 illustrates a partial side view of a chemical mechanical polishing (CMP) system 100 and components thereof. The CMP system 100 is adapted to hold a substrate 102 in relationship to a polishing pad 104 and is used to carry out a polishing process in accordance with another aspect of the invention. The substrate may be a wafer, such as a patterned wafer including partially- or fully-formed transistors thereon. The polishing pad 104 may be mounted on a conventional platen 106 that may be rotated by a suitable motor (not shown) coupled to the platen by shaft 107. Polishing pad 104 may comprise any suitable porous material, such as a soft porous polymer material. Polishing pad 104 may have a shore A hardness of about 50 or less, about 40 or less, about 30 or less, and between about 8 and about 22 in some embodiments. The polishing pad 104 may have a pore size between about 30-40 microns, and a pore rate of between 20% and 40%, for example. A POLYPAS polishing pad model H7000 from FUJIBO available from Marubeni America Corporation of Santa Clara, Calif., may be used. Other polishing pads may be used. Disc-shaped platen 106 may be rotated at between about 10-200 RPM. Other rotational speeds may be used. The substrate 102 may be held in a substrate holder 108 of conventional construction. Substrate holders (also referred to as retainers or carrier heads) are described in U.S. Pat. No. 8,298,047; U.S. Pat. No. 8,088,299; U.S. Pat. No. 7,883,397; and U.S. Pat. No. 7,459,057, issued to the present assignee, for example. Substrate holder 108 may be rotated and may also be scanned (e.g., oscillated) back and forth across the surface of the polishing pad 104 as the polishing pad 104 is being rotated in contact with the substrate 102. The holder oscillation rate may between about 0.1 mm/s and 5 mm/s. Other oscillation rates may be used. Substrate holder 108 may be rotated at between about 10-200 RPM and under a pressure of between about 0.1 and 1 psi, for example. Other rotational speeds and pressures may be used. The scanning back and forth may take place between a center and a radial side of the polishing pad 108.

A slurry 110 may be instituted and inserted between the polishing pad 104 and the substrate 102 by a distributor 112 and be used in the polishing process. Distributor 112 may be coupled to a slurry supply 114, such as by one or more suitable conduits. A pump 116 or other liquid conveying or transfer mechanism may supply a metered amount of the slurry 110 to the surface of the pad 104. In the depicted embodiment, the slurry 110 may be dispensed onto the surface of the polishing pad 104 ahead of the substrate 102 by the distributor 112 so that the slurry 110 is received in front of the substrate 102 and is drawn between the polishing pad 104 and the substrate 102 by the rotation of the pad 104 and is used to facilitate the polishing process. In the depicted embodiment, the slurry 110 comprises silicon nanoparticles. The silicon nanoparticles may be provided in a suitable carrier liquid.

Accordingly, the CMP system 100 is useful for polishing a surface of a substrate 102 as will be apparent from the following description. According to embodiments, the CMP system 100 and slurry 110 containing silicon nanoparticles is especially adapted for use in polishing a backside 215 of a substrate 102 after a previous polishing step exposing a plurality of through silicon via 220 (See FIG. 2). Through silicon via 220 generally comprise cylindrical copper pillars internal to the silicon structure of the substrate 102 and are used to establish electrical connections between stacked chips in their final form. During a previous expose polishing process, wherein the through copper vias 224 are exposed, i.e., the silicon backside 215 is removed by polishing/planarization down to the depth of the through copper vias 224, some of the removed copper is believed to be involved in a reduction reaction, which causes copper particles and/or copper oxide particles 225 (a few shown in circles) to be re-deposited onto the backside silicon surface 215 of the substrate 102 surrounding the copper vias 224.

In particular, as shown in FIG. 2, a partial view of a substrate 102 is shown. The backside 215 of the substrate 102 is polished by utilizing a previous polishing process, and then is subjected to polishing method according to embodiments of the invention where a fine slurry 110 is instituted between the backside 215 of the substrate 102 and the polishing pad 104. The slurry 110 has a composition that is adapted to chemical mechanical polishing of a substrate (e.g., wafer). In one or more embodiments, the slurry composition comprises a liquid carrier 230 and silicon nanoparticles 235 (a few labeled). The silicon nanoparticles 235 may be generally spherical in shape and may have an average particle size (e.g., diameter) of less than about 8 nanometers, less than about 6 nanometers, and between about 8 nanometers and about 3 nanometers, or even between about 6 nanometers and about 4 nanometers in some embodiments. These very small nanoparticles (e.g., being less than about 8 nanometers) provide a very large surface are is accessible for the copper reduction reaction. The silicon nanoparticles 235 may be provided in an amount of less than about 1 weight %, between about 1 weight % and about 0.01 weight %, or even between about 0.01 weight % and about 0.1 weight % in some embodiments. In accordance with another aspect, a pH of the slurry 110 may be between about 9 and about 12. Hydroxide or other source of hydroxyl ions may be added in an effective amount to bring about suitably basic conditions. For example, the Potassium hydroxide may be provided in an amount between about 0.01 weight % and about 1 weight %. In another example, hydrogen peroxide may be provided in an amount between about 0.1 weight % and about 2 weight %. The liquid carrier 230 may comprise de-ionized water. Other suitable carrier liquids may be used. Other additives and components may be added in combination with the silica nanoparticles, such as etchant chemicals and/or other sizes and types of abrasives. For example, an larger average size particle size abrasive such as silica having a weight % of between 2 weight % to about 13 weight % may be added. An etchant or other chemical may be added to control a copper removal rate. Weight % as used herein is based upon the total weight of the composition according to the formula:

Weight %=(component weight/total slurry weight)×100%

One example embodiment of a slurry 110 in accordance with an aspect of the invention is shown in Table 1.

TABLE 1
Example Slurry Composition

| Component | weight % |
|---|---|
| DIW | 86.04% |
| KOH | 0.20% |
| Silicon nanoparticles (5 nm avg. particle size) | 0.01% |
| Colloidal silica particles (80 nm avg. particle size) | 13.00% |
| BTA (Benzotriazole) | 0.15% |
| Glycine | 0.60% |
| Total | 100.00% |

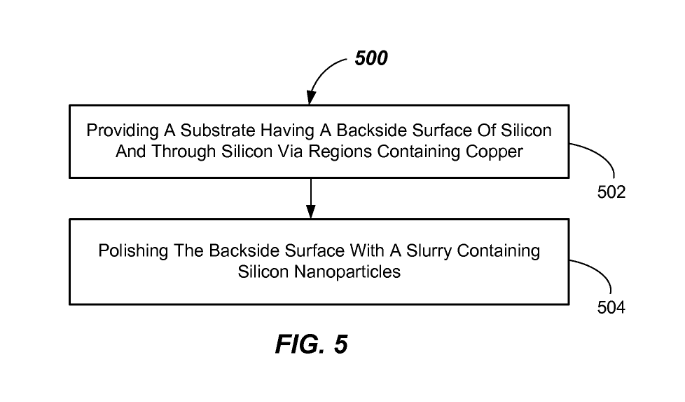

FIG. 5 illustrates a chemical mechanical polishing method 500 adapted to process a substrate (e.g., substrate 102), and in particular a method of polishing a substrate (e.g., substrate 102) after undergoing a previous planarization or other polishing process that has exposed the copper vias 220 on the backside 215 of the substrate (herein an “expose process”). However, the present method may be used on any substrate 102 having a surface (frontside or backside) having a combination of silicon and copper.

The method 500 includes, in 502, providing a substrate having a backside surface (e.g., backside surface 215) of silicon and through silicon via regions containing copper (220), and in 504 polishing the backside surface with a slurry (e.g., slurry 110) containing silicon nanoparticles (e.g., silicon nanoparticles 235). Prior to the polishing step according to embodiments of the present invention, an expose process has taken place on the backside 215 of the substrate 102 to remove silicon, Copper from the through silica via regions 220, and a diffusion barrier 240 prior to the polishing of the backside surface 215. The expose process may be completed on a previous platen of a multi-step CMP system.

After this preliminary expose process is completed on the backside, the polishing method 500 with the slurry containing silicon nanoparticles according to embodiments of the invention may commence. In accordance with one or more embodiments, the polishing of the backside surface 215 with the slurry 110 containing silicon nanoparticles 235 may occur for 10 seconds or more. The slurry 110 containing silica nanoparticles 235 comprises silicon nanoparticles having an average particle size of less than about 8 nanometers. In some embodiments, the polishing of the backside surface 215 with the slurry 110 containing silicon nanoparticles 235 occurs for between about 10 seconds and about 90 seconds. Other time periods may be used. Without being bound to theory, the slurry 110 containing silicon nanoparticles 235 is believed to function as a reducing agent to deposit copper onto the surface of the silicon nanoparticles 235. The polishing method 500 including the slurry 110 of nanoparticles 235 functions as a reducing agent to remove copper particles surrounding the through silicon via 220 to the extent where only particles of less than 20 nanometers remain, if any. Thus, the method 500 provides defect reduction for Cu/Si TSV CMP.

In the more general case, a chemical mechanical polishing method of processing a substrate is provided. The method includes providing a substrate having a surface containing silicon and copper; and polishing the surface with a slurry containing silicon nanoparticles. The method may be carried out by a chemical mechanical polishing (CMP) system. Embodiments of the present system may be used whenever both Cu and silicon are exposed during CMP, regardless if the exposure is the substrate “frontside” or “backside” and regardless if the regions of Cu at issue extend completely through the silicon-containing substrate or not.

For example, copper defects may exist when processing Si/Cu on a wafer frontside, and even in the case where the copper regions only extend partially (not fully through) the silicon substrate. The system includes a substrate held in a substrate holder, the substrate having a surface containing silicon and copper, a polishing pad, and a slurry containing silicon nanoparticles inserted between the substrate and the polishing pad. The silicon nanoparticles may have an average particle size of less than about 8 nanometers. Other suitable slurry components may be used such as DIW, a pH control agent (e.g., OH or KOH), other abrasives such as larger colloidal silica particles (e.g., >50 nanometers), inhibitors and/or complexing agents. For example, the slurry may contain colloidal silica particles of up to 13 weight %. These particles may have an average particle size of greater than 50 nm, or even about 80 nanometers. The slurry may have up to about 0.15 wt % of an inhibitor, such as BTA (Benzotriazole). Further, the slurry may have up to about 0.6 wt % of a complexing agent, such as Glycine. Other additives may be included.

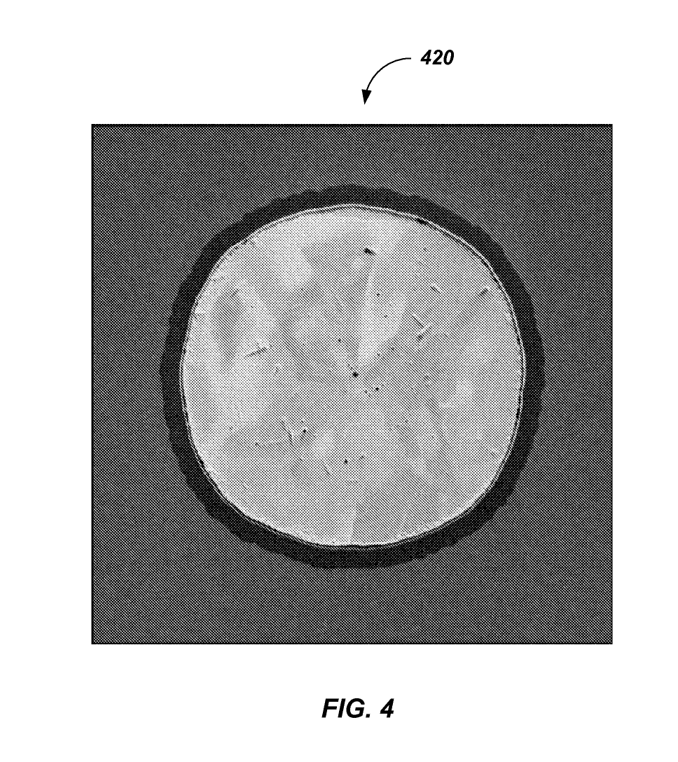

FIG. 4 illustrates a micrograph of through silica via 420 with the copper particles being removed around the via after undergoing the CMP method 500 at 1 psi pressure applied to the substrate 102 and with silicon nanoparticles 235 having a average particle size of 5 nanometers and weight percent of about 1.5 weight % for 30 seconds according to an embodiment of the invention.

Accordingly, while the present invention has been disclosed in connection with example embodiments thereof, it should be understood that other embodiments may fall within the scope of the invention, as defined by the following claims.

1. A slurry composition adapted to chemical mechanical polishing of a wafer, the composition comprising:
a liquid carrier; and
silicon nanoparticles having an average particle size of less than about 8 nanometers and in an amount between about 0.01 weight % and about 0.1 weight %,
wherein the pH of the composition is between about 9 and about 12.

2. The slurry composition of claim 1, wherein the liquid carrier comprises de-ionized water.

3. (canceled)

4. The slurry composition of claim 1, wherein the silicon nanoparticles comprise an average particle size of between about 3 nanometers and about 8 nanometers.

5. The slurry composition of claim 1, wherein the silicon nanoparticles comprise an average particle size of less than about 6 nanometers.

6. The slurry composition of claim 1, comprising colloidal silica particles having an average particle size greater than 50 nanometers, an inhibitor, and a complexing agent.

7. A chemical mechanical polishing system, comprising:
a substrate held in a substrate holder, the substrate having a backside surface of silicon and through silicon via regions of copper;
a polishing pad;
a slurry containing silicon nanoparticles inserted between the substrate and the polishing pad.

8. The chemical mechanical polishing system of claim 7, wherein the polishing pad comprises a polymer having a durometer of less than about 50 shore A.

9. A chemical mechanical polishing method of processing a substrate, comprising:
providing the substrate having a backside surface of silicon and through silicon via regions containing copper; and
polishing the backside surface with a slurry containing silicon nanoparticles.

10. The method of claim 9, comprising polishing the substrate to remove silicon, Cu from the through silicon via regions, and a diffusion barrier prior to the polishing of the backside surface with the slurry containing silicon nanoparticles.

11. The method of claim 9, wherein the slurry containing silicon nanoparticles comprises silicon nanoparticles having an average particle size of less than about 8 nanometers.

12. The method of claim 9, wherein the slurry containing silicon nanoparticles comprises silicon nanoparticles having an average particle size of less than about 6 nanometers.

13. The method of claim 9, wherein the polishing of the backside surface with the slurry containing silicon nanoparticles occurs for 10 seconds or more.

14. The method of claim 13, wherein the polishing of the backside surface with the slurry containing silicon nanoparticles occurs for between about 10 seconds and about 90 seconds.

15. The method of claim 9, wherein the slurry containing silicon nanoparticles functions as a reducing agent to deposit copper onto the surface of the silicon nanoparticles.

16. The method of claim 15, wherein the polishing functions as a reducing agent to remove copper particles surrounding the through silicon via to the extent where only particles of less than 20 nanometers remain, if any.

17. A chemical mechanical polishing method of processing a substrate, comprising:
providing a substrate having a surface containing silicon and copper; and
polishing the surface with a slurry containing silicon nanoparticles.

18. The chemical mechanical polishing method of claim 17 wherein the silicon nanoparticles have an average particle size of less than about 8 nanometers.

19. The chemical mechanical polishing method of claim 17 wherein the silicon nanoparticles are provided in an amount between about 0.01 weight % and about 0.1 weight %.

20. A chemical mechanical polishing system, comprising:
a substrate held in a substrate holder, the substrate having a surface of silicon and copper;
a polishing pad;
a slurry containing silicon nanoparticles inserted between the substrate and the polishing pad.
